(19) United States
(12) Patent Application Publication
(10) Pub. No.: US 2022/0102345 A1
(43) Pub. Date: Mar. 31, 2022

(54) PLURALITY OF 3D VERTICAL CMOS DEVICES FOR HIGH PERFORMANCE LOGIC

(71) Applicant: Tokyo Electron Limited, Tokyo (JP)

(72) Inventors: Mark I. GARDNER, Cedar Creek, TX (US); H. Jim FULFORD, Marianna, FL (US)

(73) Assignee: Tokyo Electron Limited, Tokyo (JP)

(21) Appl. No.: 17/335,563

(22) Filed: Jun. 1, 2021

Related U.S. Application Data
(60) Provisional application No. 63/085,547, filed on Sep. 30, 2020.

(51) Int. Cl. H01L 27/092; H01L 29/78; H01L 27/12; H01L 21/8238; H01L 21/822

(52) U.S. Cl. CPC H01L 27/092; H01L 29/7827; H01L 21/8221; H01L 21/823885; H01L 27/1203

(57) ABSTRACT

Techniques herein include methods for fabricating vertical stacks of vertical-channel transistors. Vertical channels can be made from an initial epitaxial structure, and electrically isolated at locations to divide the structure into multiple, independent vertical channels. Techniques enable modulating PMOS and NMOS channel composition and channel geometry to match drive currents thereby providing advanced circuit tuning. Advantageously, one process step can be performed per type of epitaxial material to dope epitaxial materials in respective source/drain regions.

### CROSS REFERENCE TO RELATED APPLICATIONS

This present disclosure claims the benefit of U.S. Provisional Application No. 63/085,547, filed on Sep. 30, 2020, which is incorporated herein by reference in its entirety.

### FIELD OF THE INVENTION

The present disclosure relates to microelectronic devices including semiconductor devices, transistors, and integrated circuits, including methods of microfabrication.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

In the manufacture of a semiconductor device, for example especially on the micro- or nanoscale, various fabrication processes are executed such as film-forming depositions, etch mask creation, patterning, material etching and removal, and doping treatments. These processes are performed repeatedly to form desired semiconductor device elements on a substrate. With microfabrication, transistors have been created in one plane with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

3D integration, i.e. the vertical stacking of multiple devices, aims to overcome these scaling limitations by increasing transistor density in volume rather than area. Although device stacking has been successfully demonstrated and implemented by the flash memory industry with the adoption of 3D NAND, application to random logic designs is more difficult. Thus, 3D integration for logic chips (e.g. CPU (central processing unit), GPU (graphics processing unit), FPGA (field programmable gate array), and SoC (system on a chip)) is desired.

### SUMMARY

The present disclosure relates to semiconductor device, including a first transistor disposed on a substrate and including a first channel, current flow through the first channel being perpendicular to a surface of the substrate; and a second transistor disposed overtop the first transistor and including a second channel, current flow through the second channel being perpendicular to the surface of the substrate, wherein the first transistor and the second transistor form a first stack, a length of the first channel of the first transistor is defined by a thickness of a first dielectric layer in the first transistor, and a length of the second channel of the second transistor is defined by a thickness of a second dielectric layer in the second transistor.

The present disclosure additionally relates to a method of fabricating a semiconductor device, including forming a multilayer stack on a surface of a substrate including a semiconductor material, the multilayer stack including a plurality of dielectric layers, the plurality of dielectric layers having at least three different dielectric materials having different etch selectivities to one another, a first dielectric layer of the plurality of dielectric layers having a first thickness corresponding to a first channel length, and a second dielectric layer of the plurality of dielectric layers having a second thickness corresponding to a second channel length; forming at least one opening through the multilayer stack to a first layer of the semiconductor material of the substrate; growing, epitaxially in the at least one opening, one or more channel materials to form channels such that current flowing through the channels flows perpendicular to the surface of the substrate; and removing portions of the plurality of dielectric layers around the one or more channel materials but not immediately proximal to the plurality of dielectric layers in the at least one opening to form sidewall structures surrounding the plurality of dielectric layers.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1 is a cross-sectional substrate segment including deposited layers of different dielectric types, according to an embodiment of the present disclosure.

FIG. 2 is a cross-sectional substrate segment illustrating etching of the stack 100, according to an embodiment of the present disclosure.

FIG. 3 is a cross-sectional substrate segment illustrating epi growth, according to an embodiment of the present disclosure.

FIG. 4 is a cross-sectional substrate segment illustrating gate region definition, according to an embodiment of the present disclosure.

FIG. 5 is a cross-sectional substrate segment illustrating dielectric deposition, according to an embodiment of the present disclosure.

FIG. 6 is a cross-sectional substrate segment illustrating N+ epitaxial growth, according to an embodiment of the present disclosure.

FIG. 7 is a cross-sectional substrate segment illustrating protective oxide deposition, according to an embodiment of the present disclosure.

FIG. 8 is a cross-sectional substrate segment illustrating a second protective oxide deposition, according to an embodiment of the present disclosure.

FIG. 9 is a cross-sectional substrate segment illustrating gate formation, according to an embodiment of the present disclosure.

FIG. 10 illustrates examples of 3D CMOS combinations, according to an embodiment of the present disclosure.

FIG. 11 illustrates additional examples of 3D CMOS combinations, according to an embodiment of the present disclosure.

FIG. 12 illustrates additional examples of 3D CMOS combinations, according to an embodiment of the present disclosure.

FIG. 13 is a flow chart for a method of fabricating a semiconductor device, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Described herein are 3D complementary metal-oxide-semiconductor (CMOS) devices and methods. Embodiments include vertical stacks of vertical channel transistors. Vertical channels can be made from an initial epitaxial structure, and electrically isolated at locations to divide the structure into multiple, independent vertical channels. Embodiments enable different channel lengths, which is highly beneficial for making 3D or stacked devices monolithically. Techniques described herein enable modulating PMOS and NMOS channel composition and channel geometry to match drive currents, thereby providing advanced circuit tuning. Columns of source/drain (S/D) devices can have epitaxial (commonly referred to as “epi”) growth for the entire vertical stack. Also, complimentary field effect transistors (CFETs) and any combination of n-type metal-oxide-semiconductor (NMOS) or p-type metal-oxide-semiconductor (PMOS) circuits and S/D elements can be achieved with techniques described herein. By combining sequentially grown epi layers, a plurality of stacked devices can be fabricated.

Embodiments herein include vertical stacks of vertical channel transistors that can be N transistors tall. That is, any number, N, of transistors tall. S/D formation can be executed with one process step even with different types of transistors in different locations across the substrate. Any semiconductor material can be used for the three epi regions, which can define the channel region, to optimize the device properties. CFET stacks can be combined or integrated with all possible 3D logic transistor combinations to achieve circuit elements in close proximity for high speed and optimum layout. Embodiments include all essential logic and memory circuit elements (NMOS, PMOS, inverter, diodes, etc.) made with techniques described herein.

Embodiments will now be described with reference to accompanying drawings.

In one example, vertical channels can be epitaxially grown with three epitaxial regions and with an adjacent dielectric stack. In the same example, the dielectric stack includes five materials with two or more channel lengths for the different CMOS devices. That is, the different CMOS devices can include different diameters of the channel. Each stack can include N different channel lengths and diameters or cross sectional area with different epitaxial stacks for each device region. Embodiments enable forming a CFET device or any combination of 3D or stacked device types. The number of 3D transistors can be N. In one example, combinations of different 3D CMOS devices can be achieved using the described techniques herein.

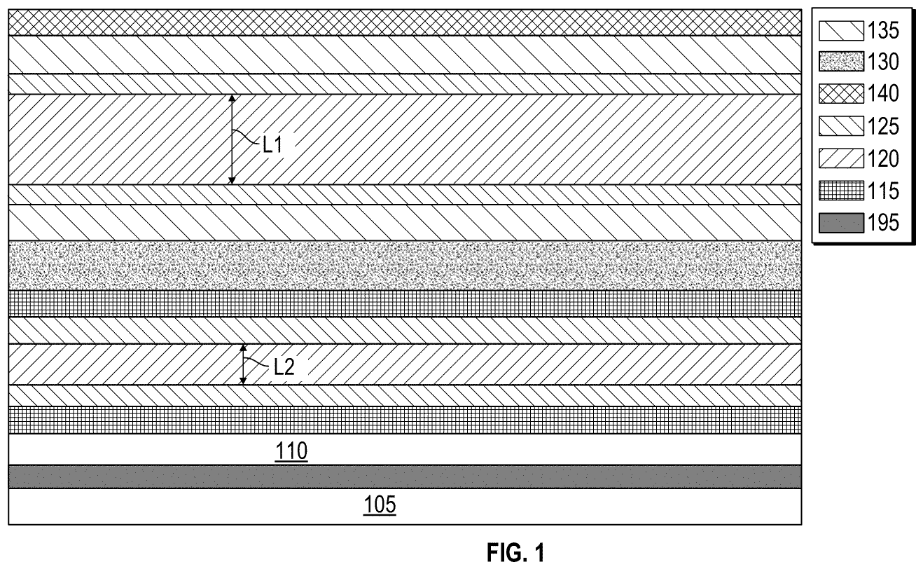

Referring now to the figures, FIG. 1 is a cross-sectional substrate segment including deposited layers of different dielectric types, according to an embodiment of the present disclosure. In an embodiment, as shown in FIG. 1, a multilayer stack 100 (herein referred to as “stack 100”) can include a substrate 105, an oxide 195 disposed overtop the substrate 105, and a single crystal semiconductor (SC S) 110 disposed overtop the oxide 195. In sequential order moving further from the SCS 110, the stack 100 can include a first dielectric 115, a third dielectric 125, a second dielectric 120, the third dielectric 125, the first dielectric 115, a fourth dielectric 130, a fifth dielectric 135, the third dielectric 125, the second dielectric 120, the third dielectric 125, the fifth dielectric 135, and a hard mask 140 deposited overtop the fifth dielectric 135.

In an embodiment, the second dielectric 120 sandwiched between the third dielectric 125 and the fifth dielectric 135 can comprise a first (upper) transistor and have a first channel length equal to a thickness of the second dielectric 120 in said respective first transistor, as denoted by L1. The second dielectric 120 sandwiched between the third dielectric 125 and the first dielectric 115 can comprise a second (lower) transistor and have a second channel length equal to a thickness of the second dielectric 120 in said respective second transistor, as denoted by L2. Each of the first transistor, the second transistor, and any other number N of transistors formed can be isolated from one another. To this end, the fourth dielectric 130 can be used as an isolation region in additional transistors and the second dielectric 120 can be used to define channel regions in the additional transistors (as they do for the first transistor and the second transistor).

The substrate 105 can include the SCS 110 on the oxide 195 (as shown), or include just the underlying oxide layer 195 on a wafer. The stack 100 can be formed with successive depositions of various dielectric materials that are selective to one another, meaning that a given material can be etched without substantially etching other materials. That is, there are one or more etchants and/or etching conditions such that a given one of the first dielectric 115, the second dielectric 120, the third dielectric 125, the fourth dielectric 130, and the fifth dielectric 135 can be etched without etching (or substantially etching) another. The first dielectric 115, the second dielectric 120, the third dielectric 125, the fourth dielectric 130, and the fifth dielectric 135 can be deposited by processes known by those skilled in the art. Advantageously, the first channel length L1 and the second channel length L2 can be adjusted by varying the thickness of the second dielectric 120 in the respective transistors, and additional channel lengths in additional transistors can be defined by varying the thickness of additional layers of the second dielectric 120 deposited in the additional transistors.

An example dielectric scheme can include oxide-based SiOx, SiOxNy based, high-k based, and high-k OxNy based. With high-k materials, changing an element used with high-k with oxide can cause selectivity also within the different types of high-k. Either wet etch or dry etch can be used. To further enhance selectivity options, all wet etch, all dry etch, or a combination of wet and dry etch also provides more options for a selectivity scheme of three or more materials. As previously mentioned, the stack 100 can include a number of replicated transistor levels N provided the etching options provide sufficient desired selectivity between the various dielectrics.

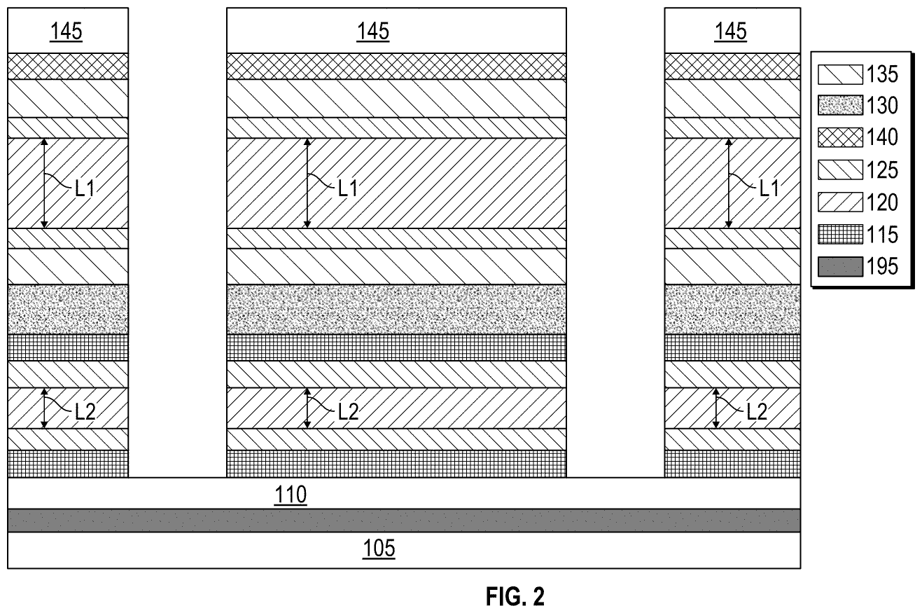

In an embodiment, after forming the stack 100, an etch mask 145 can be formed overtop the hard mask 140 to define openings in the stack 100 to form vertical channels. To this end, FIG. 2 is a cross-sectional substrate segment illustrating etching of the stack 100, according to an embodiment of the present disclosure. In an embodiment, the etch mask 145 can be deposited on the stack 100 and subsequently patterned using, for example, photlithography. The etch mask 145 can be used to create openings in the stack 100 via, for example, etching. The stack 100 is etched until reaching the underlying semiconductor material, which can be the SCS 110 or any other semiconductor material/combination. Notably, the size of the etch mask 145 can define a cross-sectional area of the resulting devices.

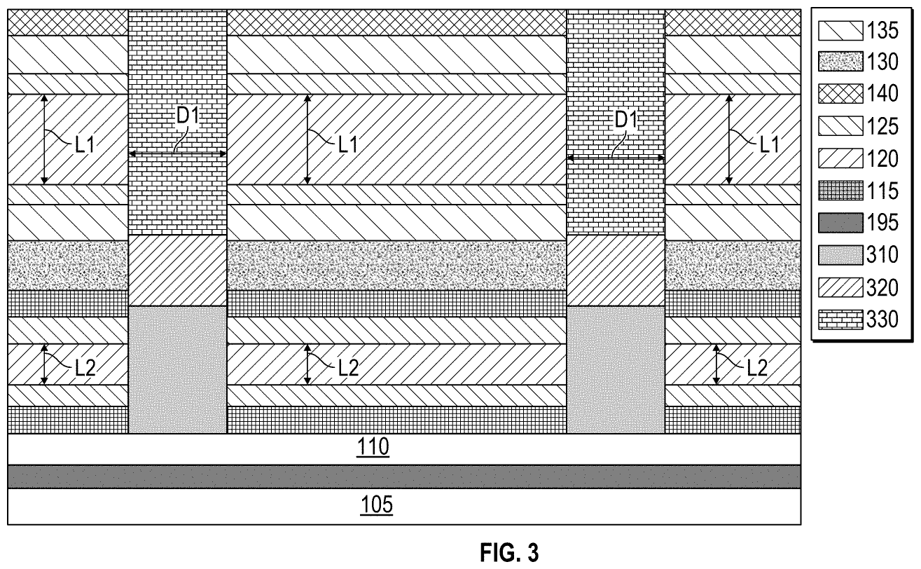

FIG. 3 is a cross-sectional substrate segment illustrating epi growth, according to an embodiment of the present disclosure. In an embodiment, devices can be grown in the recesses defined by the etch. The etch mask 145 can be removed, followed by growth of a first epitaxial layer 310 (herein referred to as “first epi 310”), a second epitaxial layer 320 (herein referred to as “second epi 320”), and a third epitaxial layer 330 (herein referred to as “third epi 330”). For the first epi 310, the second epi 320, and the third epi 330, any semiconductor element or compound can be selected for growth for a given epitaxial layer. Various options are available and known in the art. For example, two epi layers could be the same or all three epi layers could be the same. For example, each layer can be in-situ doped or intrinsically grown. The composition of the first epi 310, the second epi 320, and the third epi 330 can be based on desired circuit features (e.g. NMOS versus PMOS, channel regions, and S/D regions). Furthermore, within the first epi 310, the second epi 320, and/or the third epi 330 can be a dopant gradient. For example, there can be a grading of up to a subset of three doping levels in the first epi 310, which can range from N+, intrinsic, to P+. Additionally, the second epi 320 and the third epi 330 can include a subset of doping levels that are the same or different entirely from the first epi 310 doping level subset. Note that the width of the first epi 310, the second epi 320, and the third epi 330 can be defined by D1, as shown. This growth defines the channel regions as seen by, for example, the first epi 310 and the third epi 330 with the second epi 320 separating the aforementioned example channel regions, wherein the second epi 320 aligns with the fourth dielectric 130 that separates the two transistors.

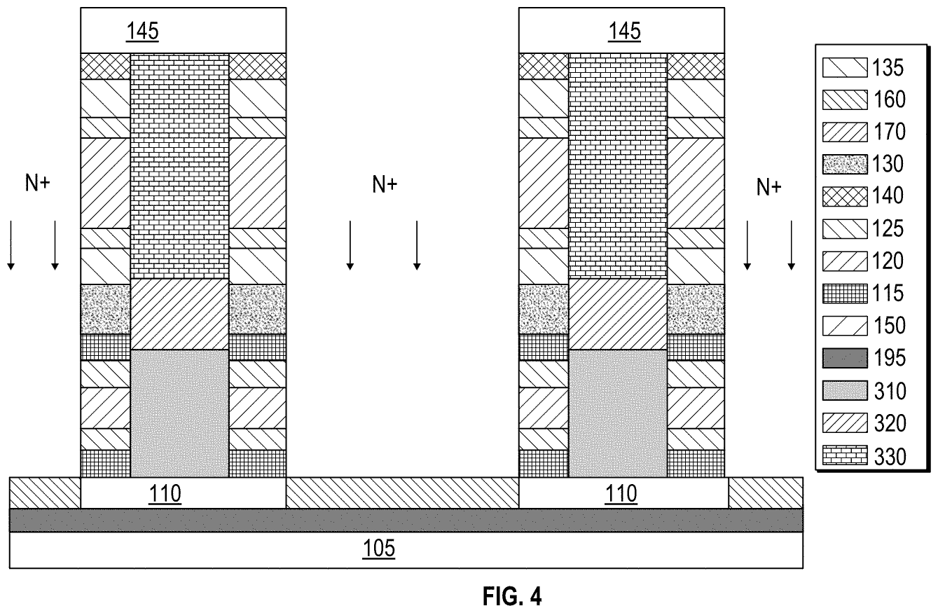

FIG. 4 is a cross-sectional substrate segment illustrating gate region definition, according to an embodiment of the present disclosure. In an embodiment, the etch mask 145 can be formed and patterned again to cover the newly grown epi layers for the channel regions (i.e. the first epi 310, the second epi 320, and the third epi 330). Notably, the etch mask 145 can extend a distance exceeding the width D1 of the newly grown epi layers. The etch mask 145 can be formed to protect predetermined areas while an etch etches through the hardmask 140 and the dielectric layers, down to the SCS 110. This can leave a thickness of the dielectric layer stack around (or on sides of) the first epi 310, the second epi 320, and the third epi 330 (i.e. the channel regions). The etch can be followed by doping the underlying SCS 110. In this example, the doping can be a N+ implant if the second (lower) transistor is to be an NMOS device. For a PMOS device at the second (lower) transistor, P+ implantation can be executed.

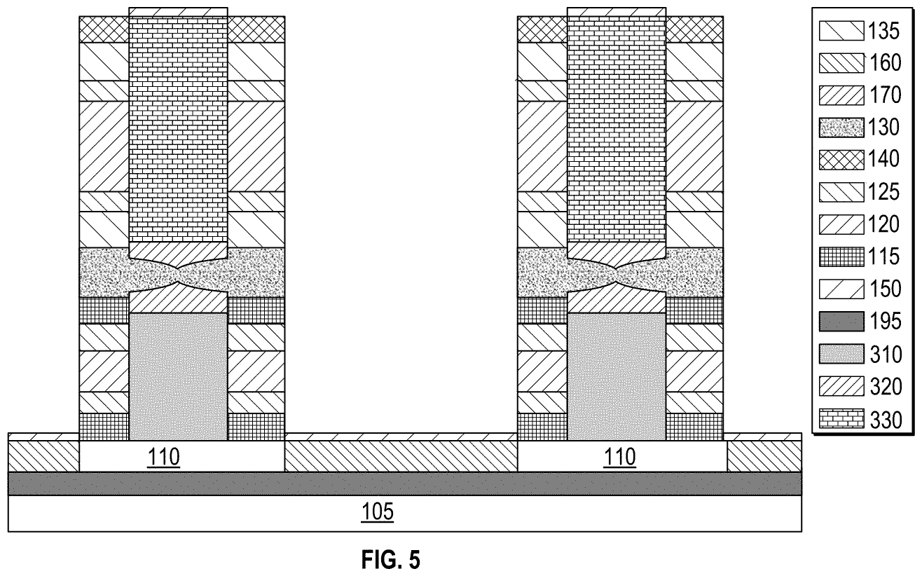

FIG. 5 is a cross-sectional substrate segment illustrating dielectric deposition, according to an embodiment of the present disclosure. In an embodiment, the etch mask 145 can then be removed, followed by deposition of a selective oxide 510 on uncovered semiconductor material (i.e. underlying layers and tops of the vertical channel regions). Also shown, an optional electric isolation region can also be formed via the fourth dielectric 130 to isolate the first (upper) transistor from the second (lower) transistor and form multiple vertical channels. For an example where the stack 100 includes additional transistors, the isolation region can be formed between each transistor. The optional isolation region is included and shown throughout the rest of the figures, but it may be appreciated the isolation region need not be formed. Thus, two or more vertical channels can be created this way.

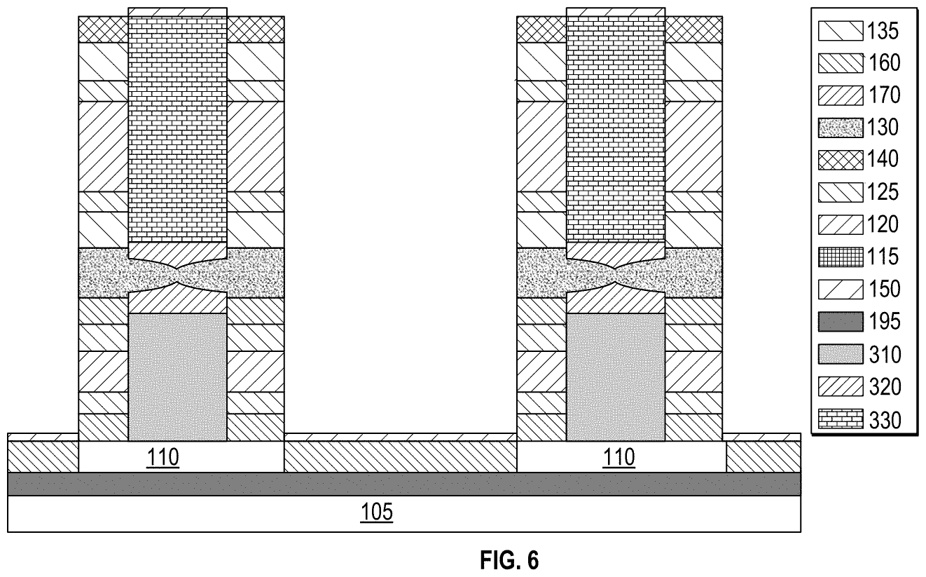

FIG. 6 is a cross-sectional substrate segment illustrating N+ epitaxial growth, according to an embodiment of the present disclosure. In FIG. 6, the first dielectric 115 is removed, followed by growth of an N+ epi 160 to form S/D regions for the second (lower) transistor. Notably, the S/D regions can be formed for multiple stacked vertical transistors this way, depending on the number of vertical transistors in a given stack. Additionally, the S/D regions among an array of transistors and at different levels can all be formed at the same time.

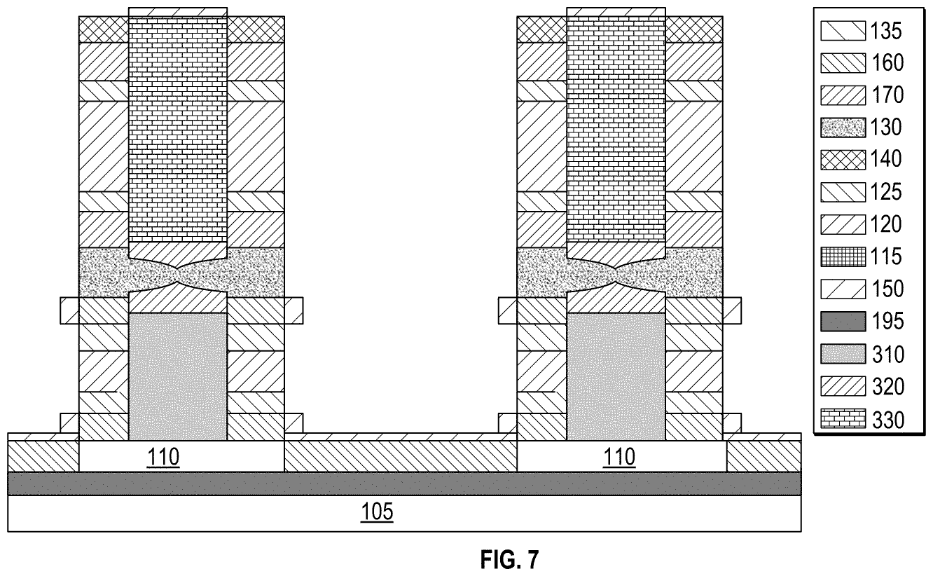

FIG. 7 is a cross-sectional substrate segment illustrating protective oxide deposition, according to an embodiment of the present disclosure. After formation of the S/D regions, the selective oxide 150 can be deposited to cover the N+ epi 160 S/D regions. Similarly, after the N+ epi 160 S/D regions are protected, the fifth dielectric 135 can be removed followed by growth of a P+ epi 170 to form the P+ epi 170 S/D regions for the first (upper) transistor. Advantageously, doping of the P+ epi 170 S/D regions can be performed while the N+ epi 160 S/D regions are still protected.

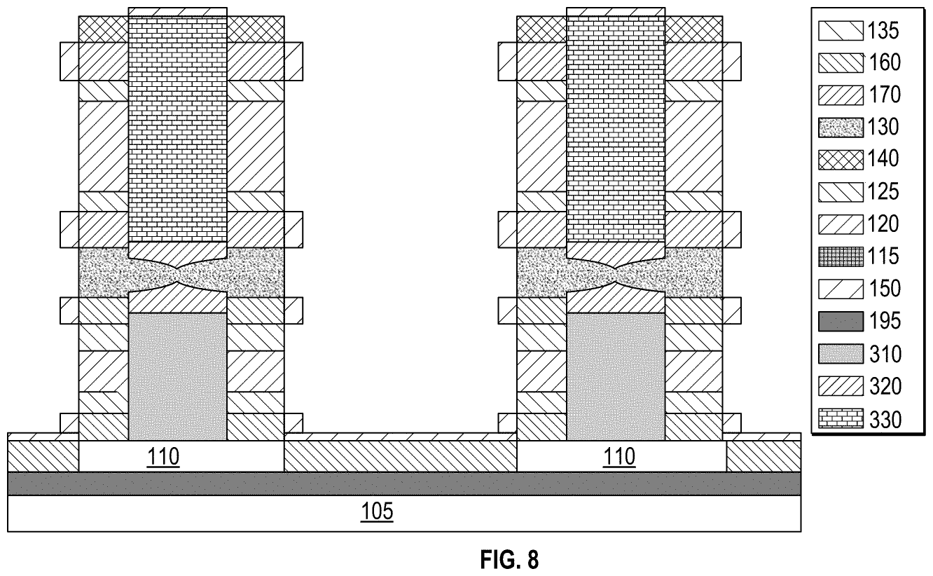

FIG. 8 is a cross-sectional substrate segment illustrating a second protective oxide deposition, according to an embodiment of the present disclosure. In an embodiment, the P+ epi 170 S/D regions can then be covered by deposition of the selective oxide 150. At this point, an optional silicidation can be performed, wherein the selective oxide 150 is removed and a silicide is formed in the same location. Alternatively, salicidation can be executed at a later time prior to electrical contact formation.

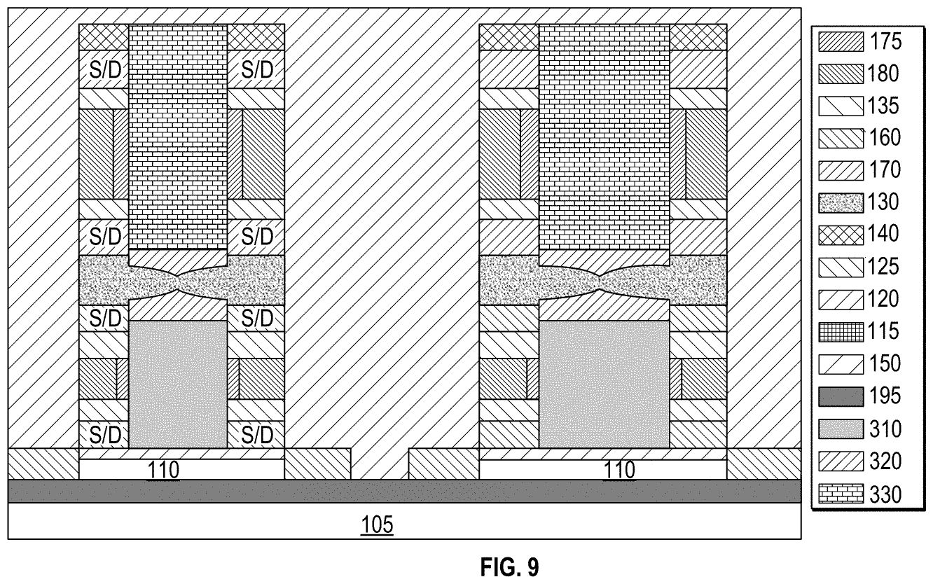

FIG. 9 is a cross-sectional substrate segment illustrating gate formation, according to an embodiment of the present disclosure. In an embodiment, the second dielectric 120 can be removed, followed by deposition of a high-k gate dielectric 175 in the same location along the exposed channel regions. Then, a metal gate 180 can be deposited and etched to complete gate electrode region formation. It may be appreciated that a different metal stack can be formed for NMOS versus PMOS by selective masking of transistor stacks and/or selective removal of dielectric sidewall materials.

FIG. 9 also illustrates an optional cut in the implanted SCS 110 layer between the two stacks of dielectric material. Notably, this can be performed prior to deposition of the dielectric layers using the etch mask 145, or during implantation of the SCS 110. In such a way, the cut electrically isolates the two resulting stacks of transistors. While generally optional, the cut can be preferred in a case where, for example, one stack of transistors includes a lower NMOS transistor and the adjacent stack of transistors includes a lower PMOS transistor.

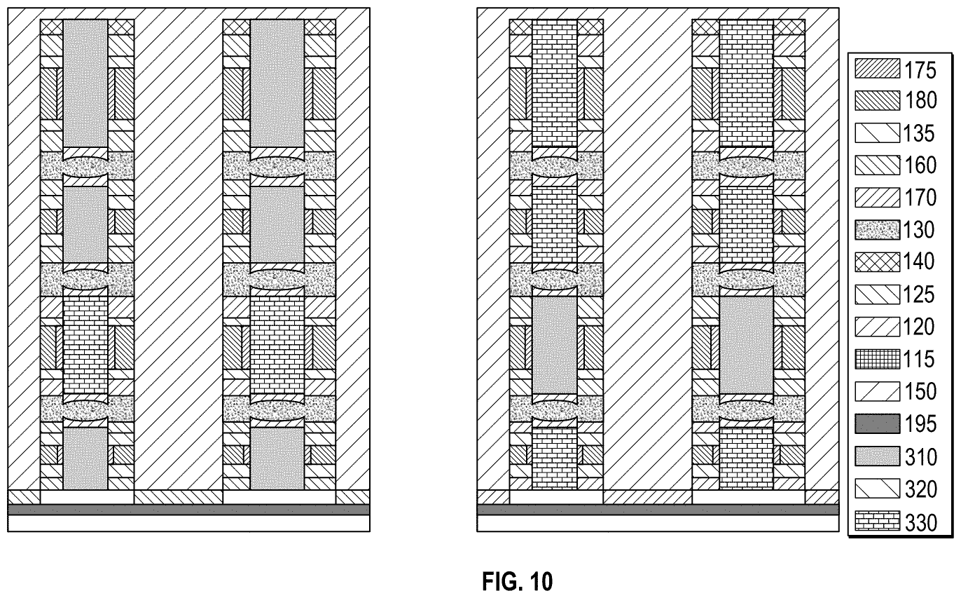

FIGS. 10-12 are cross-sectional substrate segments illustrating examples of 3D CMOS combinations, according to an embodiment of the present disclosure. Benefits and features provided by techniques herein include enabling a stack of 3D devices to be N transistors tall. All S/D formation dopant type can be performed with one process step even with different types of transistors in different 3D locations. That is, one process step can be performed per epi type—one for the N+ epi 160 S/D regions and one for the P+ epi 170 S/D regions, regardless of the number of transistors in the stack 100. Any material (i.e. semiconductor material) can be used for the three or more epi regions as this defines the channel regions to optimize device properties. CFET stacks can be combined with all possible combinations to achieve the circuit elements in close proximity for high speed and optimum layout for vertical CMOS. Furthermore, any logic and memory circuit elements can be made (i.e. NMOS, PMOS, inverter, diodes, etc.).

FIG. 10 illustrates examples of 3D CMOS combinations, according to an embodiment of the present disclosure. In an embodiment, each example includes a four-transistor 3D stack. Other stacks can have more transistors. The left stacks include a stack of two NMOS devices on top of CFET pairs. For the NMOS devices, the first epi 310 can be Si, the second epi 320 can be Si, and the third epi 330 can be Si. For the CFET pairs, the first epi 310 can be SiC, the second epi 320 can be Si, and the third epi 330 can be SiGe. The right stacks include a stack of two PMOS devices on top of CFET pairs. For the PMOS devices, the first epi 310 can be SiGe, the second epi 320 can be Si, and the third epi 330 can be SiGe. For the CFET pairs, the first epi 310 can be Si, the second epi 320 can be Si, and the third epi 330 can be Ge.

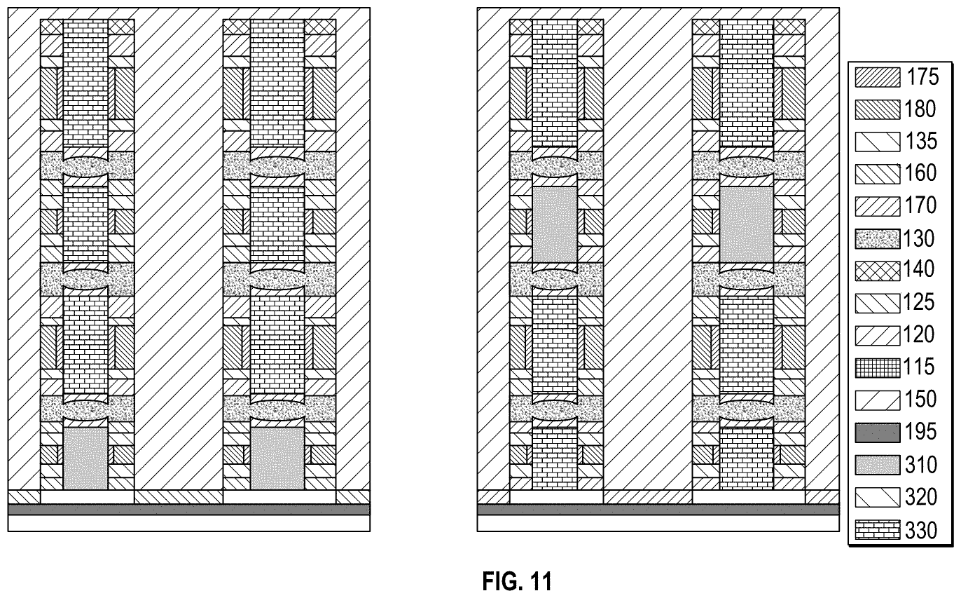

FIG. 11 illustrates additional examples of 3D CMOS combinations, according to an embodiment of the present disclosure. In an embodiment, each example includes a four-transistor 3D stack. The left stacks include a stack of three PMOS devices on top of an NMOS device. For the PMOS devices, the first epi 310 can be Ge, the second epi 320 can be Si, and the third epi 330 can be Ge. For the NMOS device, the first epi 310 can be SiC, the second epi 320 can be Si, and the third epi 330 can be SiGe. The right stacks include CFET pairs over a stack of two PMOS devices. For the CFET pairs, the first epi 310 can be Si, the second epi 320 can be Si, and the third epi 330 can be Ge. For the PMOS devices, the first epi 310 can be SiGe, the second epi 320 can be Si, and the third epi 330 can be SiGe.

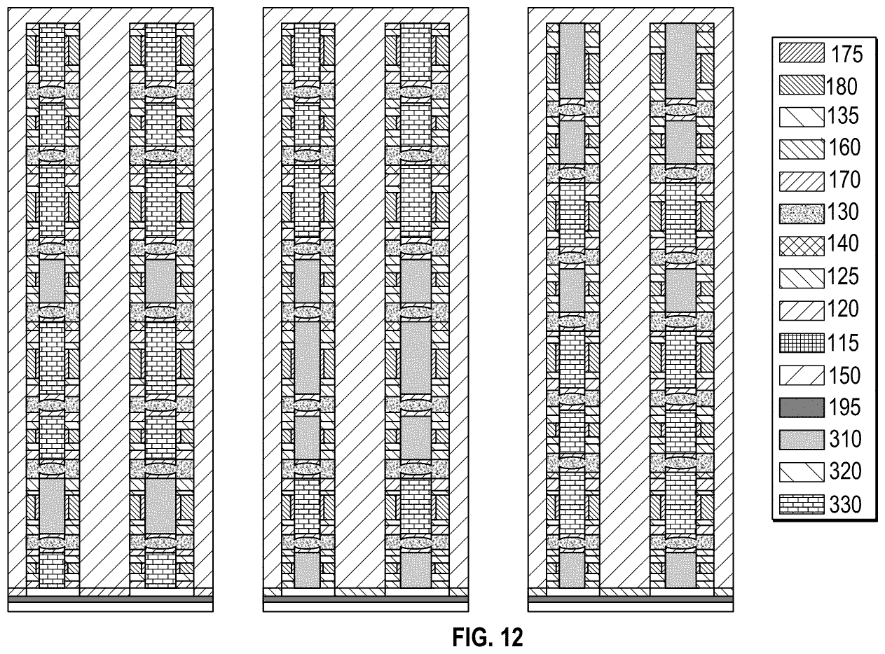

FIG. 12 illustrates additional examples of 3D CMOS combinations, according to an embodiment of the present disclosure. In an embodiment, the example vertical channel transistor stack can include eight transistors in a given stack. Accordingly, N transistor tall stacks can be created. It may be appreciated that 3D stacking of the various epi regions can include other elements not mentioned.

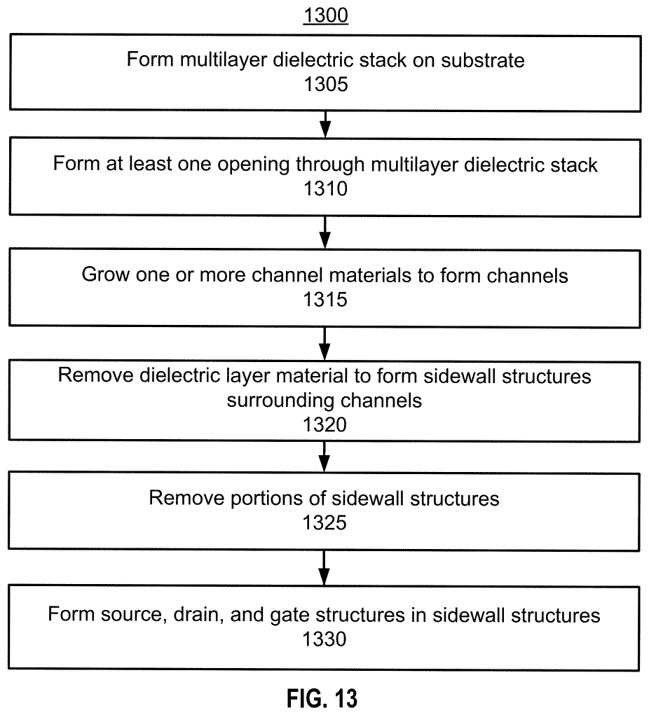

FIG. 13 is a flow chart for a method 1300 of fabricating a semiconductor device, according to an embodiment of the present disclosure.

In step 1305, the stack 100 is formed on a surface of the substrate 105, the stack 100 including the plurality of dielectric layers, the SCS 110, and the oxide 195.

In step 1310, at least one opening is formed through the stack 100.

In step 1315, one or more channel materials are grown in the at least one opening. For example, the first epi 310, the second epi 320, and the third epi 330 are grown, but additional epitaxial materials can be grown therein.

In step 1320, portions of the plurality of dielectric layers around the grown epi layers are removed. Notably, portions of the plurality of dielectric layers proximal to the grown epi layers can be preserved via using the etch mask 145 with additional overhang extending beyond the width of the grown epi layers to form sidewall structures.

In step 1325, portions of the sidewall structures are removed.

In step 1330, source, drain, and gate structures are formed in the removed portions of the sidewall structures. Notably, an optional silicide can be formed on the uncovered portions of the channel material before forming the source and drain structures.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
a first transistor disposed on a substrate and including a first channel, current flow through the first channel being perpendicular to a surface of the substrate; and
a second transistor disposed overtop the first transistor and including a second channel, current flow through the second channel being perpendicular to the surface of the substrate, wherein
the first transistor and the second transistor form a first stack,
a length of the first channel of the first transistor is defined by a thickness of a first dielectric layer in the first transistor, and
a length of the second channel of the second transistor is defined by a thickness of a second dielectric layer in the second transistor.

2. The device of claim 1, further comprising a first gate stack formed around the first channel and a second gate stack formed around the second channel.

3. The device of claim 2, wherein a type of the first transistor is PMOS or NMOS and a type of the second transistor is NMOS or PMOS.

4. The device of claim 3, wherein the type of the first transistor is PMOS or NMOS and the type of the second transistor is complementary to the first transistor type.

5. The device of claim 1, wherein the length of the first channel is different from the length of the second channel.

6. The device of claim 1, wherein
a channel region extends between the first transistor and the second transistor and includes the first dielectric layer in the first transistor and the second dielectric layer in the second transistor, and
the channel region includes a third dielectric layer disposed between the first dielectric layer in the first transistor and the second dielectric layer in the second transistor, the third dielectric layer configured to electrically isolate the first transistor and the second transistor.

7. The device of claim 6, further comprising at least one additional transistor including a respective additional channel formed overtop the second transistor, the channel region extending between the first transistor, the second transistor, and the third transistor, the channel region including at least one additional dielectric layer forming the additional channel in the additional transistor, an additional layer of the third dielectric layer disposed between the at least one additional dielectric layer, the additional layer of the third dielectric layer being configured to electrically isolate the second transistor from the at least one additional transistor.

8. The device of claim 1, further comprising
a third transistor and a fourth transistor forming a second stack disposed adjacent to the first stack, the fourth transistor disposed overtop the third transistor, the third transistor including a third channel in plane with the first transistor, current flow through the third channel being perpendicular to the surface of the substrate, the fourth transistor including a fourth channel in plane with the second transistor, and current flow through the fourth channel being perpendicular to the surface of the substrate, wherein
a length of the third channel of the third transistor is defined by a thickness of the first dielectric layer in the third transistor, and
a length of the fourth channel of the fourth transistor is defined by a thickness of the second dielectric layer in the fourth transistor.

9. The device of claim 8, further comprising
an oxide layer disposed overtop the substrate; and
a single crystal semiconductor (SCS) layer disposed overtop the oxide layer and below the first transistor, the SCS layer being doped, wherein
the SCS layer is doped based on the type of the first transistor, and
the first transistor and the third transistor are electrically connected via a portion of the doped SCS layer extending between the first transistor and the third transistor.

10. The device of claim 9, wherein the type of the first transistor is complementary to a type of the third transistor and the portion of the doped CSC layer extending between the first transistor and the third transistor is removed to electrically isolate the first transistor from the third transistor.

11. A method of fabricating a semiconductor device, comprising:
forming a multilayer stack on a surface of a substrate including a semiconductor material, the multilayer stack including a plurality of dielectric layers, the plurality of dielectric layers having at least three different dielectric materials having different etch selectivities to one another, a first dielectric layer of the plurality of dielectric layers having a first thickness corresponding to a first channel length, and a second dielectric layer of the plurality of dielectric layers having a second thickness corresponding to a second channel length;
forming at least one opening through the multilayer stack to a first layer of the semiconductor material of the substrate;
growing, epitaxially in the at least one opening, one or more channel materials to form channels such that current flowing through the channels flows perpendicular to the surface of the substrate; and
removing portions of the plurality of dielectric layers around the one or more channel materials but not immediately proximal to the plurality of dielectric layers in the at least one opening to form sidewall structures surrounding the plurality of dielectric layers.

12. The method of claim 11, further comprising
removing predetermined portions of the sidewall structures; and
forming source, drain, and gate structures in the removed predetermined portions of the sidewall structures.

13. The method of claim 12, wherein forming source, drain, and gate structures in the removed predetermined portions of the sidewall structures further comprises
removing a first dielectric material of the at least three different dielectric materials and growing a first type of epitaxial material in the removed portion of the first dielectric material;
depositing a selective oxide over the first type of epitaxial material; and
removing a second dielectric material of the at least three different dielectric materials and growing a second type of epitaxial material in the removed portion of the second dielectric material.

14. The method of claim 13, wherein forming source, drain, and gate structures in the removed predetermined portions of the sidewall structures further comprises doping the second type of epitaxial material in the removed portion of the second dielectric material without doping the first type of epitaxial material in the removed portion of the first dielectric material.

15. The method of claim 13, wherein forming source, drain, and gate structures in the removed predetermined portions of the sidewall structures further comprises
depositing a selective oxide over the second type of epitaxial material;
removing a third dielectric material of the at least three different dielectric materials and growing a third type of epitaxial material in the removed portion of the second dielectric material.

16. The method of claim 15, further comprising forming a silicide along the uncovered one or more channel materials before growing the third type of epitaxial material.

17. The method of claim 15, wherein the first type of epitaxial material and the second type of epitaxial material comprise the source and drain structures, and the third type of epitaxial material comprises the gate structure.

18. The method of claim 11, wherein
a first transistor is formed in the multilayer stack, the first transistor including a first channel comprised of a first channel material of the one or more channel materials,
a second transistor is formed in the multilayer stack disposed overtop the first transistor, the second transistor including a second channel comprised of a second channel material of the one or more channel materials, and
the first transistor and the second transistor form a first stack.

19. The method of claim 18, wherein
a third transistor is formed in the multilayer stack, the third transistor including a third channel in plane with the first transistor and comprised of the first channel material of the one or more channel materials, and
a fourth transistor is formed in the multilayer stack disposed overtop the third transistor, the fourth transistor including a fourth channel in plane with the second transistor and comprised of the second channel material of the one or more channel materials.

20. The method of claim 18, wherein growing the one or more channel materials further comprises growing a third channel material of the one or more channel materials between the first channel material and the second channel material of the one or more channel materials, the third channel material being configured to electrically isolate the first channel of the first transistor from the second channel of the second transistor.
